(19) United States
(12) Patent Application Publication
(10) Pub. No.: US 2018/0122679 A1
(43) Pub. Date: May 3, 2018

(54) STRESS BALANCED ELECTROSTATIC SUBSTRATE CARRIER WITH CONTACTS

(71) Applicant: APPLIED MATERIALS, INC., Santa Clara, CA (US)

(72) Inventors: Shambhu N. Roy, Fremont, CA (US); Gautam Pisharody, Newark, CA (US); Seshadri Ramaswami, Saratoga, CA (US); Srinivas D. Nemani, Sunnyvale, CA (US); Zhong Qiang Hua, Saratoga, CA (US); Douglas A. Buchberger, JR., Livermore, CA (US); Niranjan Kumar, Santa Clara, CA (US); Ellie Y. Yieh, San Jose, CA (US)

(21) Appl. No.: 15/337,973

(22) Filed: Oct. 28, 2016

(51) Int. Cl. H01L 21/683; H01L 21/67

(52) U.S. Cl. CPC H01L 21/6833; H01L 21/67248

(57) ABSTRACT

A substrate carrier with contacts is described that is balanced for thermal stress. In one example workpiece carrier has a rigid substrate configured to support a workpiece to be carried for processing, a first dielectric layer over the substrate, an electrostatic conductive electrode over the first dielectric layer to electrostatically hold the workpiece to be carried, a second dielectric layer over the electrode to electrically isolate the workpiece from the electrode, and a third dielectric layer under the substrate to counter thermal stress applied to the substrate by the first and second dielectric layers.

### FIELD

The present description relates to the field of semiconductor and micromechanical substrate processing using a substrate carrier in a chamber and, in particular, to a carrier with balanced stress against temperature changes.

### BACKGROUND

In the manufacture of semiconductor chips, a workpiece, such as a silicon wafer or other substrate is exposed to a variety of different processes in different processing chambers. The chambers may expose the water to a number of different chemical and physical processes whereby minute integrated circuits and micromechanical structures are created on the substrate. Layers of materials which make up the integrated circuit are created by processes including chemical vapor deposition (CVD), physical vapor deposition (PVD), epitaxial growth, and the like. Some of the layers of material are patterned using photoresist masks and wet or dry etching techniques.

The processing chambers used in these processes typically include a substrate support, pedestal, or chuck to support the substrate during processing. In some processes, the pedestal may include an embedded heater to control the temperature of the substrate and, in some cases, to provide elevated temperatures that may be used in the process. An electrostatic chuck (ESC) has one or more embedded conductive electrodes to generate an electric field that holds the wafer on the chuck using static electricity.

Due to the increased market for mobile devices, electronic chip packages are being made denser. More chips are being housed in a single package and the packages are being made smaller. This is accomplished in part by thinning the die or the wafer on which the die is formed. Most of the thickness of a semiconductor die is the wafer and not the electronic circuitry, so thinning the wafer can significantly reduce the size of a die. However, a very thin wafer may be easily bent or broken and this puts the electronic circuitry at risk. Wafers are sometimes attached to a temporary carrier with adhesives prior to prior to thinning and post-thinning processing through processes such as lithography, cleans, anneals, CVD, PVD, Plating, CMP and potentially wafer level test. Later, the wafer is de-bonded or separated from the carrier.

### SUMMARY

A substrate carrier with contacts is described that is balanced for thermal stress. In one example workpiece carrier has a rigid substrate configured to support a workpiece to be carried for processing, a first dielectric layer over the substrate, an electrostatic conductive electrode over the first dielectric layer to electrostatically hold the workpiece to be carried, a second dielectric layer over the electrode to electrically isolate the workpiece from the electrode, and a third dielectric layer under the substrate to counter thermal stress applied to the substrate by the first and second dielectric layers.

### BRIEF DESCRIPTION OF THE DRAWINGS

Embodiments of the present invention are illustrated by way of example, and not limitation, in the figures of the accompanying drawings in which:

FIG. 1 is an isometric exploded diagram of a carrier for holding a workpiece according to an embodiment.

FIG. 2 is a partial cross-sectional side view of an assembled carrier for holding a workpiece according to an embodiment.

FIG. 3 is a partial cross-sectional side view of an alternative assembled workpiece carrier according to an embodiment.

FIG. 4 is a cross-sectional side view diagram of an electrical contact mounted in a portion of the workpiece carrier of FIG. 3 according to an embodiment.

FIG. 5 is a bottom plan view of a workpiece carrier showing a hole in the wafer with a sleeve resting inside according to an embodiment.

FIG. 6 is a graph of current over time of power from a carrier power supply according to an embodiment.

FIG. 7 is an isometric view of an assembled electrostatic chuck holding a workpiece carrier according to an embodiment.

FIG. 8 is a schematic of a plasma etch system including a chuck assembly in accordance with an embodiment of the present invention.

### DETAILED DESCRIPTION

As described herein, a workpiece carrier may be fabricated using a regular silicon wafer or other similar rigid material as a substrate and a polyimide or other dielectric-based ESC (Electrostatic Chuck) that is bonded to the wafer. A silicon water substrate gives the carrier the characteristics of a standard wafer including flatness, total thickness variations, mechanical stiffness, and thermal conductivity. Similar results may be obtained with other glass and ceramic substrates. A silicon wafer may be chucked electrically to the carrier. The chucked assembly or workpiece and carrier may be handled and processed using standard tools. This construction also allows the paired workpiece carrier and process wafer to have an extended retention time. The process wafer is retained by the workpiece carrier until such time that the process wafer needs to be separated from the carrier.

The thinned wafer is easily separated electrostatically or by gas, air, or lift pins or some combination at the end of processing. While it may be difficult to bond and de-bond a wafer with adhesives, with the ESC approach the wafer is easily attached and removed from the carrier. In addition, an ESC with a silicon substrate can be processed in typical semiconductor processing tools. The carrier and thinned wafer have dimensions similar to that of a regular wafer and can be assembled onto a standard wafer carrier for processing.

The polyimide ESC includes a monopolar, bi-polar, or any other electrode pattern formed of a conductive thin electrode encapsulated by two polyimide or dielectric thin sheets. This allows the carrier's ESC to sustain very high voltages due to the established insulating properties of polyimide films.

A second dummy ESC having a substantially similar if not identical construction as the top ESC stack may be bonded to the back of the carrier's silicon wafer substrate. This allows for bonding at higher temperatures. The additional dummy ESC also increases the carrier's operating temperature range. The increase is due at least in part to the upper and lower polyimide stacks balancing any CTE (Coefficient of Thermal Expansion) mismatch between the polyimide and the silicon. The CTE mismatch can otherwise cause mechanical stress, warping, and bending of the polyimide relative to the silicon wafer substrate.

The carrier's polyimide ESC uses electrodes that are charged and discharged through contacts. The contacts for the electrodes may be fabricated using a conductive metal, such as conductive molybdenum or titanium, as a button directly in contact with the electrodes and held inside an insulating shell. Molybdenum provides better chemical resistance than copper and other materials, but any other conductive material may be used for the contact buttons or for the electrodes. The shell isolates the buttons from the bulk silicon wafer substrate. This isolation allows for a semi-conductive silicon even a conductive substrate material to be used without affecting the electrode contact buttons.

The substrate silicon wafer may be prepared before the polyimide layers are attached. There are many established techniques for processing silicon wafers and any of these may be used. The wafer may be laser drilled for contact holes and gas holes. The holes will have side walls that are cylindrical or in some other shape between the top and bottom flat surfaces of the wafer. Since the silicon has some electrical conductivity, the side walls of the holes may be covered with an insulator in any of a variety of different ways. The deposition method and thickness of the insulator can be adjusted to suit different uses. As an example, insulating oxide layers (e.g. SiO₂) may be deposited.

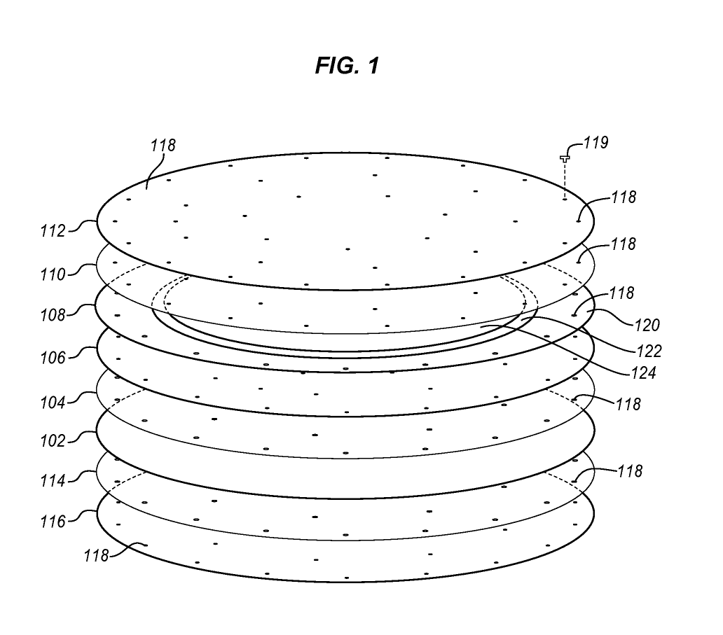

FIG. 1 is an isometric exploded diagram of a carrier suitable for arse in holding a workpiece, such as a thinned wafer. The thinned wafer may be made of silicon, glass, silica, alumina, gallium arsenide, lithium niobate, indium phosphide, or any of a variety of other materials. The carrier is based on a standard wafer substrate 102. In embodiments, the substrate is made of a wafer that has a CTE close to or the same as that of the workpiece that is to be carried. The substrate may also be the same material. In the examples described herein, the workpiece is a thinned or standard thickness silicon wafer and the substrate is a standard silicon wafer, but this is not necessary. The workpiece and substrate may be formed of other materials, depending on the processes to be performed and the devices that are to be formed on the workpiece. For a thinned silicon wafer, a silicon wafer substrate 102 is particularly suitable, but other materials may be used instead. The carrier is shown as round and may be 200 mm or 300 mm in diameter and 0.75 or 1 mm thick, but other shapes and sizes may alternatively be used.

A polyimide sheet 106 is cut into an appropriate shape, in this case a 200 mm circle, and attached to the wafer substrate 102 with an adhesive 104. An electrode 106 is attached to the polyimide sheet and a second top polyimide sheet 112 is attached over the electrode 106 with another adhesive layer 110. The polyimide sheets are dielectric and serve as isolators for the electrode. The isolated electrode is therefore able to store a charge which is used to generate an electrostatic force to grip the workpiece (not shown) over the top of the top sheet. While polyimide is mentioned here any of a variety of other dielectric materials, including other types of polymers may be used.

The polymer or dielectric coating could be laminated, spun-on or deposited using other techniques. The coating may be a single layer or a multi-layer dielectric stack. For example, a dielectric stack may have a layer of a material with a different dielectric constant or other properties compared to the polymer film. In this example, a laminated polymer construct is shown. The layers of the laminate are assembled with adhesives.

The electrode is shown as a concentric electrode. It has an outer annulus 120 of conductive material, such as copper, an inner annulus 124 of the same conductive material and a dielectric boundary 122 shown as a thin ring between the two. The surface area of each annulus is large compared to the wafer substrate in order to store a large amount of charge. Typically, the outer annulus will have an opposite charge from the inner annulus. This increases the grip on the workpiece. The concentric electrodes are provided as an example, any other electrode configuration suitable to grip the thinned workpiece may be used. The electrode may be formed independently of the polyimide sheets for example by electroplating, screen printing, sputter deposition, foil lamination, or in other ways and applied to the sheets. The electrode is held in place by being sandwiched between the polyimide sheets. Alternatively, the electrode may be applied to the base polyimide sheet 106 by spin-coating, electroplating or some other technique before or after the sheet is attached to the wafer.

A further layer of polyimide 116 is optionally bonded to the bottom of the substrate wafer 102 with another layer of adhesive. This third layer electrically insulates the bottom of the substrate wafer. In many usage scenarios, the bottom of the carrier will be held in an electrostatic or a vacuum chuck. The bottom surface may be selected to optimize the grip of the chuck. Different bottom surface treatments may be used to suit different applications. Mechanical roughening, plasma treatment, reactive gas treatment or some other processes may be used to treat the surface and increase the adhesive force between the surfaces

As shown, each layer has many holes 118 distributed throughout its surface. These holes are examples in number and location. The particular number and arrangement of holes may be adapted to suit any of a variety of different process applications. These holes may be combined with or replaced by trenches, slits, cavities or other structures. These holes are aligned through each of the layers to provide a passageway for gas to pass through the final completed assembly. These holes may be vacuum holes, cooling gas holes, lift pin holes, or holes for any other purpose. Different holes may be used for different purposes.

If the carrier wafer assembly is placed on a vacuum chuck and a workpiece is placed over the carrier assembly, then suction from the vacuum chuck may be allowed to pass through vacuum holes so that the workpiece and the carrier wafer may be held in place by the vacuum chuck. If the wafer carrier and a wafer are placed in a chamber for thermal processing, a cooling gas may be pumped through gas holes to promote heat conduction from the workpiece to the carrier. The heat from the carrier may then be conducted to a base chuck with further cooling gas or in another way.

A porous plug or an engineered plug 119 made of ceramic or another porous material may be used to cover gas holes so that an intended gas can pass through the cover but liquids and solids are restricted or blocked. A single plug is shown as an example, but a similar plug may be applied to some or all of the holes, depending on the particular implementation. The top of the plug may be used as a post to suspend the carrier above the surface of the top dielectric layer. The thickness of the top of the plug may be adapted to suit the particular implementation. Alternatively, the plug may be configured to fit completely within the hole and not extend above the top of the dielectric layer.

Lift pins may be pushed up through the holes in the workpiece carrier to push the workpiece off the carrier and release the electrostatic grip. The holes may be lined on the inner walls of the silicon with an insulating material such as an oxide (e.g. SiO₂), as mentioned above.

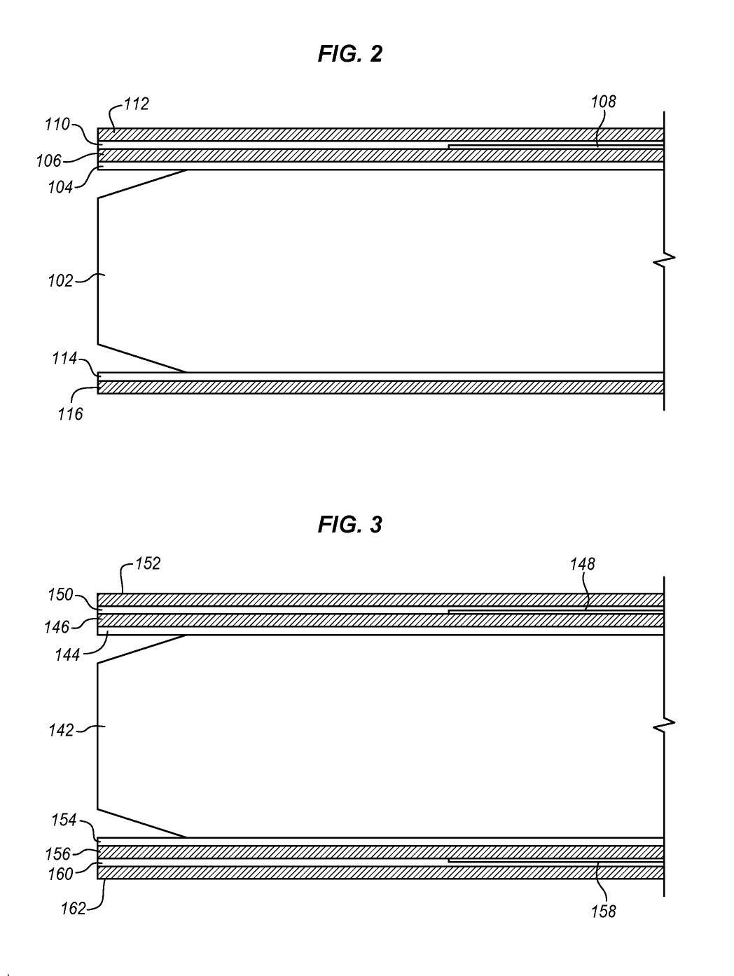

FIG. 2 is a partial cross-sectional side view of an assembled workpiece carrier as described herein. The substrate wafer 102 is located centrally with the first polyimide layer 106 and the second polyimide layer 110 attached to each other and the substrate with respective adhesive layers 104, 110. The electrode 108 is applied to the first polyimide layer. Accordingly, there is a layer of adhesive 110 and polyimide 112 between the electrode and a workpiece. Alternatively, the electrode 108 may be applied to the bottom surface of the top polyimide sheet 112. It may be attached in the same way that it is attached to the lower polyimide sheet 106. The bottom side of the substrate wafer 102 is attached to a bottom isolation layer 116 also by an adhesive 114 of any desired type. The vacuum holes 118 are not shown in order not to obscure other features in this view.

As shown, the wafer 102 is sandwiched between the top polyimide sheets 146, 152 and the bottom polyimide sheet 116. The polyimide sheets are secured to the wafer with adhesive or in any other suitable way so that any movement of the wafer applies a stress to the polyimide. In the thinned silicon wafer workpiece example, the carrier's water substrate is formed of a silicon, glass, ceramic or other similar material that has a CTE of about 2.6×10⁻⁶/degree K which is similar to that of a thinned silicon wafer workpiece. The copper electrode is about 17 and the polyimide in a range of 15-50×10⁻⁶/degree K. As a result, when the temperature of the assembly changes the e-chuck and polyimide layers will expand at a different rate from the water and the entire workpiece carrier will tend to bow, warp, or bend. The bottom polyimide layer 116, however, will counter the force of the top e-chuck layers. If the thickness of the bottom polyimide is selected to be thick enough to counter the force of the top e-chuck layers, then the forces will balance and the workpiece carrier will not bend or bow with temperature changes.

FIG. 3 is a partial cross-sectional side view of an alternative assembled workpiece carrier as described herein. This workpiece carrier has a central substrate wafer 142 with first 146 and second 152 polyimide layers attached to one side with first 144 and second 150 adhesive layers. An electrode 148 is sandwiched between the polyimide layers and held in position by the polyimide. The electrode and polyimide forms an e-chuck or electrostatic chuck (ESC) to attach a workpiece to the carrier. A dummy e-chuck is formed on the bottom side of the substrate wafer 142 in a similar way.

The dummy e-chuck also has a bottom side first polyimide layer 156 and second polyimide layer 162 held to the wafer 154 and to each other 160 by adhesive layers 154. Similarly a conductive electrode 158 is formed, placed, or mounted between the polyimide layers. The dummy e-chuck has roughly the same dimensions and materials as the top side e-chuck. As a result, it has roughly the same thermal expansion properties. While the real e-chuck will be electrostatically charged by the application of a voltage to its terminals, the dummy e-chuck is not necessarily charged and may not have any terminals at which a charge can be applied. In order to prevent any undesired behavior from the dummy e-chuck it may be electrically isolated from any external contact or it may be externally grounded so that it does not develop a charge from other external influences. When the assembly is exposed to different temperatures, the real e-chuck and the dummy e-chuck will have similar thermal expansion behavior because they are made of roughly the same or similar materials with about the same dimensions. The carrier is not able to bend or bow due to the difference in CTE between the polyimide and copper on the one hand and the silicon on the other hand.

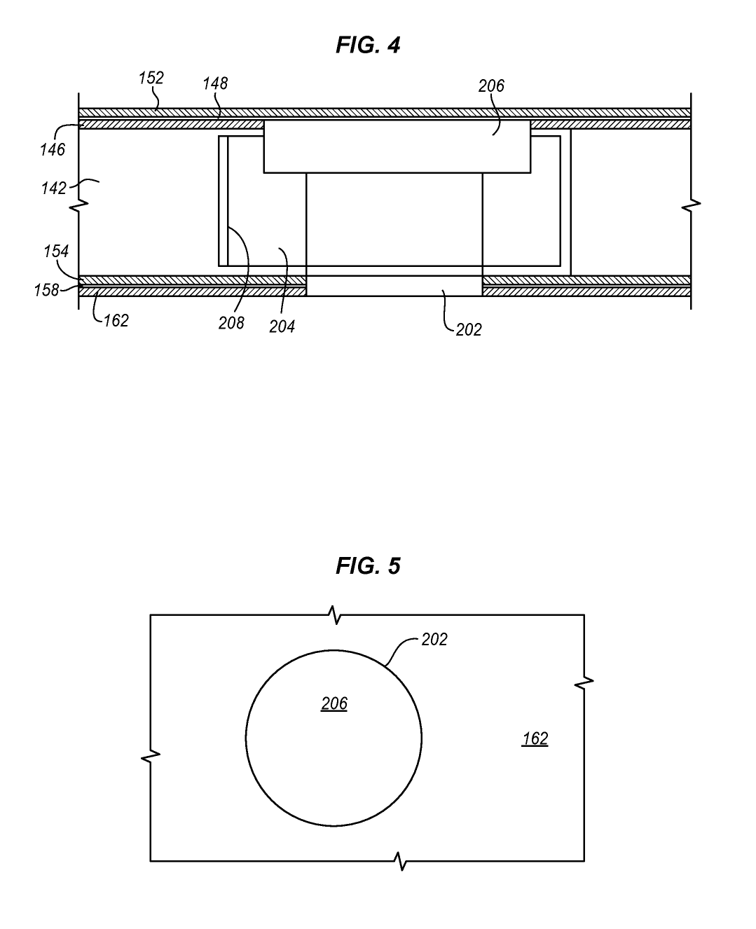

FIG. 4 is a cross-sectional side view diagram of a portion of the workpiece carrier of FIG. 3 to show an electrical contact mounted in the workpiece carrier. The electrical contact 206 provides a connection to the electrode 148 of the e-chuck. The contact allows the electrode to be charged to create the electrostatic connection to the workpiece. While only one contact is shown, there is at least one contact for each electrode component. A bipolar electrode will have at least two. There may be many more contacts for each electrode component or pole so that a charge is applied to each component of the electrode more quickly.

The workpiece carrier has a top layer electrode 148 with one or more segments sandwiched between an upper and lower dielectric layer 146, 152 such as polyimide. The top dielectric layer 152 contacts the workpiece although there may be additional intervening layers (not shown). The bottom layer 146 insulates the electrode from the bulk silicon wafer 142 and is bonded to the silicon, although there may also be additional intervening layers. There is also a bottom layer dummy electrode 158 sandwiched between layers of polyimide 154, 162 or another dielectric. As mentioned above, the lower layers may have only dielectric without the metal electrode 158. The water 142 between the top and bottom electrodes is prepared with a hole 202. The hole, like the vacuum, gas, and lift pin holes 118 may be lined with a dielectric layer (not shown) such as an insulating oxide like SiO₁, HfO₂.

A metal disc contact button 206 is placed in the hole 202 and contacts the metal electrode 148. The button electrode is placed in permanent electrical contact with the electrode and provides a thick and durable surface as compared to the electrode for the application of charging pins. To charge or discharge the electrode, charging pins are applied to the disc and a voltage is applied with a polarity that is either the same as or the opposite of the charge on the electrode. The disc may be made of a metal such as titanium, molybdenum, copper, or aluminum or of any other conductive material that can sustain multiple touches from the charging pins.

To further isolate the wafer 142 from the electrical contact button 206 an additional sleeve 204 may optionally be used. The sleeve may be made of PEEK (Polyether Ether Ketone) or another thermoplastic polymer, alumina, or another ceramic or other suitable isolating material. The sleeve 204 rests inside the hole 202 in the silicon within the inner walls 208 of the hole so that the button 206 contacts only the sleeve and the polyimide layers. The bottom dummy electrode is applied over the sleeve to hold the sleeve in place.

FIG. 5 is a bottom plan view of the wafer of the workpiece carrier showing the hole 202 in the wafer 152 with a sleeve 204 resting inside. The button 206 is centered in the sleeve and held in place by the sleeve. The button may be made to have a close fit into the sleeve pocket so that it is retained by friction and the surrounding layers. The sleeve-button assembly is held in place by the electrode polyimide layers.

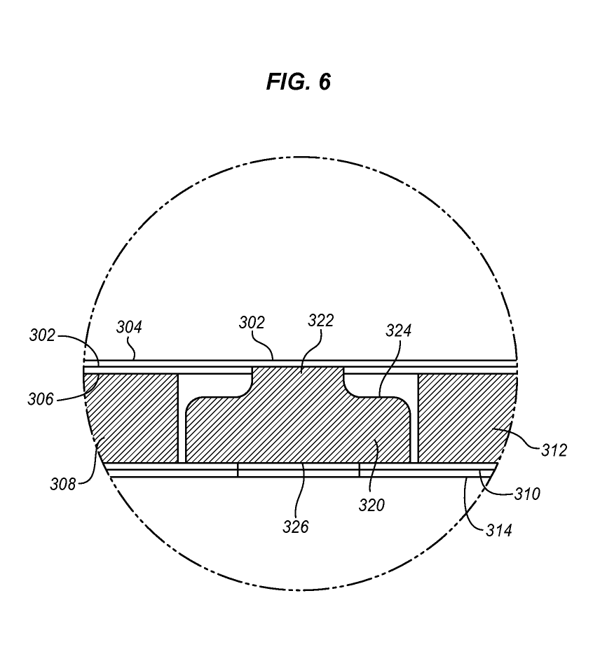

FIG. 6 is a cross-sectional side view diagram of an alternative contact button in a workpiece carrier. This version has a similar silicon, ceramic, or metal bulk substrate 308. An e-chuck is formed over the substrate with a contact electrode 302 and a dielectric layer 306 between the electrode and the substrate and another dielectric layer 304 over the electrode. This is a top side active e-chuck stack with the electrode sandwiched between two insulating polyimide or other dielectric sheets. There is a similar bottom side dummy e-chuck on the opposite side of the substrate to balance the stress caused by the top side active e-chuck. The dummy e-chuck has a metal layer 310 which may be in the form of an electrode or a simple metal layer. There is a dielectric layer above 312 and below 314 the metal layer.

A contact button 302 is inserted into a hole 316 in the dummy c-chuck and the substrate 308. In this example, the contact button has a contact pin 322 that protrudes from the main body of the button to make contact with the electrode 302 of the active c-chuck on the top side of the carrier. The main body of the button presents a contact surface 326 on the bottom of the button to make contact with charging pins inserted into the holes 316 through the bottom dummy e-chuck.

The contact button has a shoulder 324 surrounding the protruding contact pin. This shoulder may be configured to rest against a surface of the hole in the bulk substrate 308. As an example, the hole in the substrate may be drilled with a counterbore. The counterbore provides a hole with a larger area near the bottom side and a smaller area for the protruding contact pin near the top side. The contact button shoulder rests against the end of the larger area aligned so that the contact pin extends through the smaller area to the electrode. The counterbore and the shoulder protect the electrode from being pierced or bent by the contact pin. The electrode may be charged in the same way as for the other examples by applying a voltage to the contact button to charge the electrode.

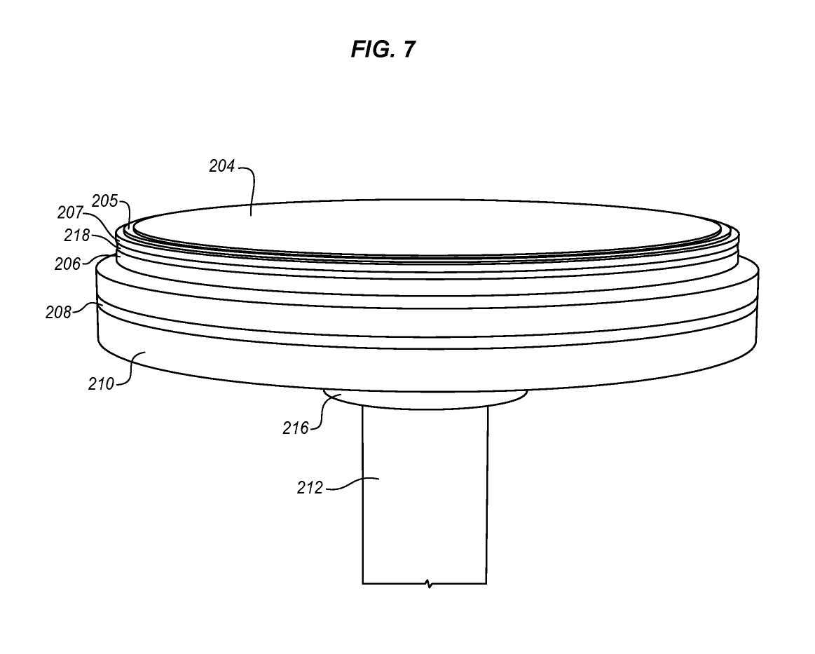

FIG. 7 is an isometric view of an assembled electrostatic chuck (ESC) holding a workpiece carrier as described herein. A support shaft 212 supports a base plate 210 through an isolator 216. A middle isolator plate 208 and an upper cooling plate 206 are carried by the base plate. The top cooling plate 206 carries a dielectric puck 205 on the top surface of the heater plate. The puck has an upper circular platform to support a workpiece chucked to a workpiece carrier 204 and a lower concentric circular base 207 to attach to the heater plate. The upper platform has internal electrodes to electrostatically attach the workpiece. The workpiece may alternately be clamped, vacuumed or attached in another way. A variety of modifications may be made to the ESC as to the number of plates, the positions and structures of heaters, cooling channels, gas flow channels, and other components.

The ESC is able to control the temperature of the workpiece using resistive heaters in the puck, coolant fluid in the cooling plate, or both. Electrical power, coolant, gases, etc. are supplied to the coolant plate 206 and the puck 205 through the support shaft. The ESC may also be manipulated and held in place using the support shaft.

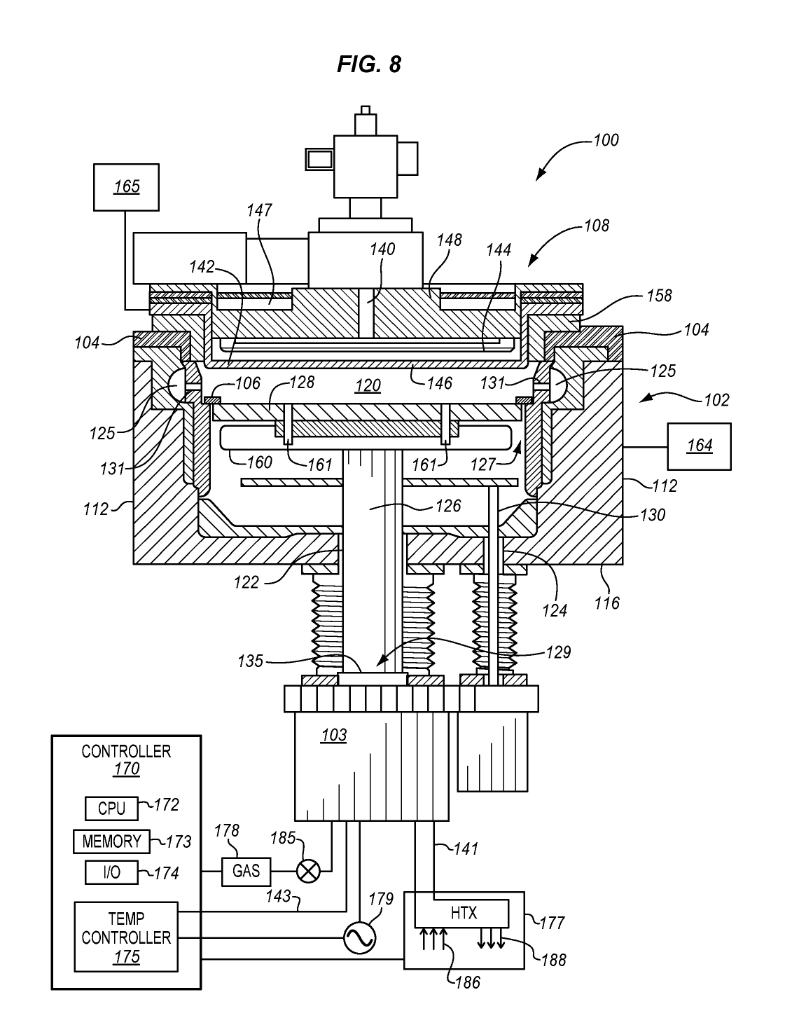

FIG. 8 is a partial cross sectional view of a plasma system 100 having a pedestal 128 according to embodiments described herein. The pedestal 128 has an active cooling system which allows for active control of the temperature of a substrate positioned on the pedestal over a wide temperature range while the substrate is subjected to numerous process and chamber conditions. The plasma system 100 includes a processing chamber body 102 having sidewalls 112 and a bottom wall 116 defining a processing region 120.

A pedestal, carrier, chuck or ESC 128 is disposed in the processing region 120 through a passage 122 formed in the bottom wall 116 in the system 100. The pedestal 128 is adapted to support a substrate (not shown) on its upper surface. The substrate may be any of a variety of different workpieces for the processing applied by the chamber 100 made of any of a variety of different materials. As described above, a workpiece chucked to a workpiece carrier may be attached to the pedestal instead of only the workpiece. The pedestal 128 may optionally include heating elements (not shown), for example resistive elements, to heat and control the substrate temperature at a desired process temperature. Alternatively, the pedestal 128 may be heated by a remote heating element, such as a lamp assembly.

The pedestal 128 is coupled by a shaft 126 to a power outlet or power box 103, which may include a drive system that controls the elevation and movement of the pedestal 128 within the processing region 120. The shaft 126 also contains electrical power interfaces to provide electrical power to the pedestal 128. The power box 103 also includes interfaces for electrical power and temperature indicators, such as a thermocouple interface. The shaft 126 also includes a base assembly 129 adapted to detachably couple to the power box 103. A circumferential ring 135 is shown above the power box 103. In one embodiment, the circumferential ring 135 is a shoulder adapted as a mechanical stop or land configured to provide a mechanical interface between the base assembly 129 and the upper surface of the power box 103.

A rod 130 is disposed through a passage 124 formed in the bottom wall 116 and is used to activate substrate lift pins 161 disposed through the pedestal 128. The substrate lift pins 161 lift the workpiece off the pedestal top surface to allow the workpiece to be removed and taken in and out of the chamber, typically using a robot (not shown) through a substrate transfer port 160.

A chamber lid 104 is coupled to a top portion of the chamber body 102. The lid 104 accommodates one or more gas distribution systems 108 coupled thereto. The gas distribution system 108 includes a gas inlet passage 140 which delivers reactant and cleaning gases through a showerhead assembly 142 into the processing region 120B. The showerhead assembly 142 includes an annular base plate 148 having a blocker plate 144 disposed intermediate to a faceplate 146.

A radio frequency (RF) source 165 is coupled to the showerhead assembly 142. The RE source 165 powers the showerhead assembly 142 to facilitate generation of plasma between the faceplate 146 of the showerhead assembly 142 and the heated pedestal 128. In one embodiment, the RF source 165 may be a high frequency radio frequency (HERE) power source, such as a 13.56 MHz RE generator. In another embodiment, RE source 165 may include a HERE power source and a low frequency radio frequency (LFRF) power source, such as a 300 kHz RE generator. Alternatively, the RF source may be coupled to other portions of the processing chamber body 102, such as the pedestal 128, to facilitate plasma generation. A dielectric isolator 158 is disposed between the lid 104 and showerhead assembly 142 to prevent conducting RE power to the lid 104. A shadow ring 106 may be disposed on the periphery of the pedestal 128 that engages the substrate at a desired elevation of the pedestal 128.

Optionally, a cooling channel 147 is formed in the annular base plate 148 of the gas distribution system 108 to cool the annular base plate 148 during operation. A heat transfer fluid, such as water, ethylene glycol, a gas, or the like, may be circulated through the cooling channel 147 such that the base plate 148 is maintained at a predefined temperature.

A chamber liner assembly 127 is disposed within the processing region 120 in very close proximity to the sidewalls 101, 112 of the chamber body 102 to prevent exposure of the sidewalls 101, 112 to the processing environment within the processing region 120. The liner assembly 127 includes a circumferential pumping cavity 125 that is coupled to a pumping system 164 configured to exhaust gases and byproducts from the processing region 120 and control the pressure within the processing region 120. A plurality of exhaust ports 131 may be formed on the chamber liner assembly 127. The exhaust ports 131 are configured to allow the flow of gases from the processing region 120 to the circumferential pumping cavity 125 in a manner that promotes processing within the system 100.

A system controller 170 is coupled to a variety of different systems to control a fabrication process in the chamber. The controller 170 may include a temperature controller 175 to execute temperature control algorithms (e.g., temperature feedback control) and may be either software or hardware or a combination of both software and hardware. The system controller 170 also includes a central processing unit 172, memory 173 and input/output interface 174. The temperature controller receives a temperature reading 143 from a sensor (not shown) on the pedestal. The temperature sensor may be proximate a coolant channel, proximate the wafer, or placed in the dielectric material of the pedestal. The temperature controller 175 uses the sensed temperature or temperatures to output control signals affecting the rate of heat transfer between the pedestal assembly 142 and a heat source and/or heat sink external to the plasma chamber 105, such as a heat exchanger 177.

The system may also include a controlled heat transfer fluid loop 141 with flow controlled based on the temperature feedback loop in the example embodiment, the temperature controller 175 is coupled to a heat exchanger (HTX)/chiller 177. Heat transfer fluid flows through a valve (not shown) at a rate controlled by the valve through the heat transfer fluid loop 141. The valve may be incorporated into the heat exchanger or into a pump inside or outside of the heat exchanger to control the flow rate of the thermal fluid. The heat transfer fluid flows through conduits in the pedestal assembly 142 and then returns to the HTX 177. The temperature of the heat transfer fluid is increased or decreased by the HTX and then the fluid is returned through the loop back to the pedestal assembly.

The HTX includes a heater 186 to heat the heat transfer fluid and thereby heat the substrate. The heater may be formed using resistive coils around a pipe within the heat exchanger or with a heat exchanger in which a heated fluid conducts heat through an exchanger to a conduit containing the thermal fluid. The HTX also includes a cooler 188 which draws heat from the thermal fluid. This may be done using a radiator to dump heat into the ambient air or into a coolant fluid or in any of a variety of other ways. The heater and the cooler may be combined so that a temperature controlled fluid is first heated or cooled and then the heat of the control fluid is exchanged with that of the thermal fluid in the heat transfer fluid loop.

The valve (or other flow control devices) between the HTX 177 and fluid conduits in the pedestal assembly 142 may be controlled by the temperature controller 175 to control a rate of flow of the heat transfer fluid to the fluid loop. The temperature controller 175, the temperature sensor, and the valve may be combined in order to simplify construction and operation. In embodiments, the heat exchanger senses the temperature of the heat transfer fluid after it returns from the fluid conduit and either heats or cools the heat transfer fluid based on the temperature of the fluid and the desired temperature for the operational state of the chamber 102.

Electric heaters (not shown) may also be used in the ESC to apply heat to the workpiece assembly. The electric heaters, typically in the form of resistive elements are coupled to a power supply 179 that is controlled by the temperature control system 175 to energize the heater elements to obtain a desired temperature.

The heat transfer fluid may be a liquid, such as, but not limited to deionized water/ethylene glycol, a fluorinated coolant such as Fluorinert® from 3M or Galdeng from Solvay Solexis, Inc. or any other suitable dielectric fluid such as those containing perfluorinated inert polyethers. While the present description describes the pedestal in the context of a PECVD processing chamber, the pedestal described herein may be used in a variety of different chambers and for a variety of different processes.

A backside gas source 178 such as a pressurized gas supply or a pump and gas reservoir are coupled to the chuck assembly 142 through a mass flow meter 185 or other type of valve. The backside gas may be helium, argon, or any gas that provides heat convection between the water and the puck without affecting the processes of the chamber. The gas source pumps gas through a gas outlet of the pedestal assembly described in more detail below to the back side of the wafer under the control of the system controller 170 to which the system is connected.

The processing system 100 may also include other systems, not specifically shown in FIG. 8, such as plasma sources, vacuum pump systems, access doors, micromachining, laser systems, and automated handling systems, inter glia. The illustrated chamber is provided as an example and any of a variety of other chambers may be used with the present invention, depending on the nature of the workpiece and desired processes. The described pedestal and thermal fluid control system may be adapted for use with different physical chambers and processes.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” my be used to indicate that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material layer with respect to other components or layers where such physical relationships are noteworthy. For example in the context of material layers, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similar distinctions are to be made in the context of component assemblies.

It is to be understood that the above description is intended to be illustrative, and not restrictive. For example, while flow diagrams in the figures show a particular order of operations performed by certain embodiments of the invention, it should be understood that such order is not required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. A workpiece carrier comprising:
a rigid substrate configured to support a workpiece to be carried for processing;
a first dielectric layer over the substrate;
an electrostatic conductive electrode over the first dielectric layer to electrostatically hold the workpiece to be carried;
a second dielectric layer over the electrode to electrically isolate the workpiece from the electrode; and
a third dielectric layer under the substrate to counter thermal stress applied to the substrate by the first and second dielectric layers.

2. The workpiece carrier of claim 1, further comprising;
a second conductive electrode under the third dielectric layer; and
a fourth dielectric layer under the second electrode together to counter thermal stress applied to the substrate by the first and second dielectric layers and by the first electrode.

3. The workpiece carrier of claim 1, wherein the rigid substrate is formed of material having a coefficient of thermal expansion similar to that of the workpiece.

4. The workpiece carrier of claim 1, wherein the rigid substrate is formed of silicon.

5. The workpiece carrier of claim 2, wherein the second electrode is electrically isolated from any electrical contacts.

6. The workpiece carrier of claim 1, further comprising;
an electrical contact coupled to the electrode; and
a through hole through the silicon substrate to allow access to the electrical contact.

7. The workpiece carrier of claim 6, wherein the electrical contact is formed of at least one of molybdenum or titanium.

8. The workpiece carrier of claim 6, further comprising a ceramic sleeve configured to fit within the through hole and to isolate the electrical contact from the substrate.

9. The workpiece carrier of claim 1, wherein the dielectric of the first dielectric layer and the second dielectric layer is a polyimide.

10. The workpiece carrier of claim 9, wherein the polyimide is formed as a sheet and attached to the substrate using an adhesive.

11. The workpiece carrier of claim 1, further comprising a plurality of gas holes to allow a gas to be passed through the carrier to a back side of the workpiece.

12. The workpiece carrier of claim 11, further comprising a porous plug on the second dielectric layer over each of the plurality of gas holes.

13. An electrostatic substrate carrier to carry a silicon wafer, the carrier comprising:
a silicon substrate having a size configured for a silicon wafer;
a first dielectric layer over the substrate;
an electrostatic conductive electrode over the first dielectric layer to electrostatically hold the wafer;
an electrical contact coupled to the electrode;
a second dielectric layer over the electrode to electrically isolate the wafer from the electrode; and
a third dielectric layer under the substrate to counter thermal stress applied to the substrate by the first and second dielectric layers, the silicon substrate and the third dielectric layer defining a through hole to allow external physical contact with the electrical contact.

14. The electrostatic substrate carrier of claim 13, wherein the electrical contact is formed of at least one of molybdenum or titanium.

15. The electrostatic substrate carrier of claim 13, further comprising a ceramic sleeve configured to fit within the through hole and to isolate the electrical contact from the substrate.

16. The electrostatic substrate carrier of claim 13, further comprising a plurality of gas holes to allow a gas to be passed through the carrier to a back side of the wafer.

17. The electrostatic substrate carrier of claim 16, further comprising a porous plug on the second dielectric layer over each of the plurality of gas holes.

18. A plasma processing chamber comprising:
a plasma chamber;
a plasma source to generate a plasma containing gas ions in the plasma chamber; and
workpiece carrier to carry a workpiece for processing within the chamber, the carrier having a rigid substrate configured to support a workpiece to be carried for processing, a first dielectric layer over the substrate, an electrostatic conductive electrode over the first dielectric layer to electrostatically hold the workpiece to be carried, a second dielectric layer over the electrode to electrically isolate the workpiece from the electrode, and a third dielectric layer under the substrate to counter thermal stress applied to the substrate by the first and second dielectric layers.

19. The chamber of claim 18, wherein the workpiece carrier includes a second conductive electrode under the third dielectric layer, and a fourth dielectric layer under the second electrode together to counter thermal stress applied to the substrate by the first and second dielectric layers and by the first electrode.

20. The chamber of claim 18, further comprising a gas source coupled to the workpiece carrier to deliver a gas to a back side of the workpiece, the workpiece carrier having a plurality of gas holes to allow the delivered gas to be passed through the carrier to the back side of the workpiece.
